(19) United States
(12) Patent Application Publication
(10) Pub. No.: US 2026/0177913 A1
(43) Pub. Date: Jun. 25, 2026

(54) THICK FILM CHEMICALLY AMPLIFIED POSITIVE TYPE RESIST COMPOSITION AND METHOD FOR MANUFACTURING RESIST FILM USING THE SAME

(71) Applicant: Merck Patent GMBH, Darmstadt (DE)

(72) Inventors: Takayuki Sao, Saga-ken (JP); Kenta Watanabe, Shizuoka (JP); Tomohide Katayama, Shizuoka (JP)

(21) Appl. No.: 19/128,239

(22) PCT Filed: Nov. 14, 2023
(86) PCT No.: PCT/EP2023/081672

§ 371 Date: May 8, 2025

(30) Foreign Application Priority Data
Nov. 17, 2022 (JP) 2022-184446

(51) Int. Cl. G03F 7/004; G03F 7/039; G03F 7/32

(52) U.S. Cl. CPC G03F 7/0045; G03F 7/0397; G03F 7/322

(57) ABSTRACT

Provided is a thick film chemically amplified positive type resist composition. A thick film chemically amplified positive type resist composition comprising an alkali-soluble resin (A) having a certain structure, a photoacid generator (B), and a solvent (C).

### BACKGROUND OF THE INVENTION

### Field of the Invention

The present invention relates to a thick film chemically amplified positive type resist composition to be used in manufacturing semiconductor devices, semiconductor integrated circuits and the like, and a method for manufacturing a resist film using the same.

### Background Art

In a process of manufacturing devices such as semiconductor, fine processing by lithographic technique using a resist has generally been employed. The fine processing process comprises forming a thin resist layer on a semiconductor substrate such as a silicon wafer, covering the layer with a mask pattern corresponding to a desired device pattern, exposing the layer with actinic ray such as ultraviolet ray through the mask, developing the exposed layer to obtain a resist pattern, and etching the substrate using the resulting resist pattern as a protective film, thereby forming fine unevenness corresponding to the above-described pattern.

Patent Document 1 discloses a positive type resist composition containing a resin that is soluble in an alkaline developer having a certain structure. Examples of the group decomposed and eliminated by the action of an acid in this resin include a t-butyl group, a t-amyl group, and a hydrocarbon group having an alicyclic structure. It is considered that this resist composition is preferably used for a thin film, and in Examples, it is disclosed that a 0.3 μm resist film is formed.

### PRIOR ART DOCUMENTS

### Patent Documents

[Patent document 1] JP 2009-244829 A

### SUMMARY OF THE INVENTION

The present inventor has considered as follows. While requiring making the resist pattern finer, there is a demand for a resist pattern that is thicker and has a higher aspect ratio in order to cope with high-energy ion implantation and the like. When forming a thick film resist pattern, unlike the case of a thin film, the performance and process conditions required for the composition are different. Therefore, there are characteristic difficulties that the required shape cannot be formed only by adjusting the viscosity of the thin film resist composition to make it thicker.

The present inventors considered that there are one or more problems that still need improvement in thick film chemically amplified positive type resist compositions and use thereof. These include, for example, the followings:

When the film thickness is increased, a scooped-out area on the top of a resist pattern wall is more pronounced. The permeability of the resist film is decreased, and the sensitivity thereof is low. The resolution is low. The process margin of the process is narrow. Rectangularity of the resist pattern is low. The development contrast is low. Shape abnormality occurs after development. Resistance to the process (for example, etching) after development of the resist pattern is low. Film loss due to development is large. The selectivity ratio of etching is low. In the case of a thick resist film, light cannot be sufficiently delivered to the bottom part. The energy for exposing the resist film increases. Variation in the amount of acid generated and the amount of diffusion is large at the upper part and the bottom part of the resist film.

A thick film chemically amplified positive type resist composition according to the present invention contains an alkali-soluble resin (A), a photoacid generator (B) and a solvent (C),
wherein,
the film thickness of the resist film formed from the thick film chemically amplified positive type resist composition is 5.0 to 50.0 μm;
the alkali-soluble resin (A) comprises at least one of the following repeating units:

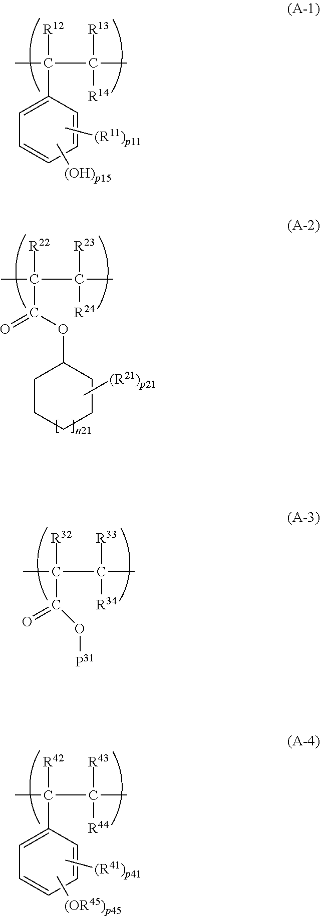

(where,
R¹¹, R²¹, R⁴¹ and R⁴⁵ are each independently C₁₋₅ alkyl (in which —CH₂— in the alkyl can be replaced with —O—);
R¹², R¹³, R¹⁴, R²², R²³, R²⁴, R³², R³³, R³⁴, R⁴², R⁴³ and R⁴⁴ are each independently hydrogen, C₁₋₅ alkyl, C₁₋₅ alkoxy or —COOH;
p11 is 0 to 4, p15 is 1 to 2, and p11+p15≤5;
p21 is 0 to 4;
n21 is 0 to 1;
p41 is 0 to 4, p45 is 1 to 2, and p41+p45≤5;
P³¹ is C₄₋₂₀ alkyl (in which the alkyl forms no ring; and all or part of H in the alkyl can be substituted with halogen); and
n_{A-1}, n_{A-2}, n_{A-3} and n_{A-4}, which are the numbers of repeating units of the repeating units (A-1), (A-2), (A-3) and (A-4) in the alkali-soluble resin (A), satisfy the following;

$${n}_{A - 1} / ( {n}_{A - 1} + {n}_{A - 2} + {n}_{A - 3} + {n}_{A - 4} ) = 0 to 80 \% ,$$

$${n}_{A - 2} / ( {n}_{A - 1} + {n}_{A - 2} + {n}_{A - 3} + {n}_{A - 4} ) = 1 to 40 \% ,$$

$${n}_{A - 3} / ( {n}_{A - 1} + {n}_{A - 2} + {n}_{A - 3} + {n}_{A - 4} ) = 0 to 40 \% , or$$

$${n}_{A - 4} / ( {n}_{A - 1} + {n}_{A - 2} + {n}_{A - 3} + {n}_{A - 4} ) = 0 to 40 \% ;$$

wherein at least one of n_{A-3}/(n_{A-1}+n_{A-2}+n_{A-3}+n_{A-4}) and n_{A-4}/(n_{A-1}+n_{A-2}+n_{A-3}+n_{A-4}) is more than 0%.

A method for manufacturing a resist film according to the present invention includes steps below:
(1) applying the above-described composition above a substrate; and
(2) heating the composition to form a resist film.

Using the thick film chemically amplified positive type resist composition according to the present invention, it is possible to desire one or more of the following effects.

The scooped-out area on the top of the resist pattern wall is suppressed. Favorable sensitivity can be obtained even with a resist film of thick film. The resolution is sufficient. The process margin of the process is sufficient. Rectangularity of the resist pattern is sufficient. The development contrast is sufficient. Shape abnormality after development hardly occurs. Film loss due to development is suppressed. In the process after development (for example, etching), a resist pattern with sufficient resistance can be obtained. The selectivity ratio of etching is sufficient. Even in the case of a thick resist film having a thickness of 5 to 50 μm, light can be sufficiently delivered to the bottom part. The energy for exposing the resist film can be suppressed. Variation in the amount of acid generated and the amount of diffusion at the upper part and the bottom part of the resist film can be reduced.

### BRIEF DESCRIPTION OF THE DRAWINGS

FIGS. 1A and 1B are schematic views showing the cross-sectional shape of a resist pattern; and

FIG. 2 is a schematic view showing the top of a resist pattern wall.

### DETAILED DESCRIPTION OF THE INVENTION

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. These copolymerization are any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (C) or another component.

Hereinafter, embodiments of the present invention are described in detail.

Thick film chemically amplified positive type resist composition

The thick film chemically amplified positive type resist composition according to the present invention (hereinafter sometimes referred to as the composition) contains an alkali-soluble resin (A), a photoacid generator (B), and a solvent (C).

The thick film resist composition means a resist composition capable of forming a resist film of thick film. In the present invention, the film thickness of the resist film formed from the thick film resist composition is 5.0 to 50 μm (preferably 11.0 to 30 μm; more preferably 11.0 to 25 μm; further preferably 11 to 20 μm).

The solid component concentration of the composition according to the present invention is preferably more than 0 mass % and less than 80 mass %, more preferably 30 to 50 mass %, and more preferably 35 to 45 mass %. The solid component concentration is the concentration of all other components except the solvent based on the composition.

The viscosity is preferably 100 to 3,000 cP, more preferably 150 to 2,500 cP, and further preferably 200 to 2,000 cP. The viscosity is measured at 25° C. with a capillary viscometer.

The composition according to the present invention is preferably a thick film chemically amplified positive type KrF resist composition. Here, the term KrF used in the above preferred examples means that a KrF excimer laser is used when exposing a resist film formed from a resist composition.

### (A) Alkali-Soluble Resin

The composition according to the present invention comprises an alkali-soluble resin (A) (hereinafter sometimes referred to as the component (A); the same applies to other components). The component (A) comprises repeating units represented by the following formulas (A-1), (A-2), (A-3) and (A-4), and comprises at least the repeating unit represented by (A-2). The component (A) is that reacts with an acid to increase its solubility in an alkaline aqueous solution. Such an alkali-soluble resin is that has, for example, an acid group protected by a protecting group, and when an acid is added from the outside, the protecting group is eliminated and the solubility in an alkaline aqueous solution is increased.

In a preferred embodiment, the repeating unit represented by (A-2) is not an acid-dissociable unit from which a protecting group is eliminated.

In the case of forming a resist pattern, it has been found that a scooped-out area tends to be generated at the top of the resist pattern wall when the film thickness increases. In the present invention, one of the features is that the component (A) comprises the repeating unit represented by the formula (A-2) having an alicyclic structure, and thus the scooped-out shape can be improved. This is not bound by theory, but is considered as follows.

When the resist film thickness increases, the amount of light reaching the bottom part decreases, so that it is considered that it is necessary to increase the exposure energy amount. When the exposure energy is large, a large amount of acid due to the photoacid generator is generated and easily diffused in the resist film upper part to which light reaches in a large amount. As a result, it is considered that the acid derived from the photoacid generator permeates and diffuses from the exposed region to the film upper part of the unexposed region, and the portion is largely dissolved at the time of development to have a scooped-out shape. In the present invention, it is considered that by including the repeating unit represented by the formula (A-2) and having properties required as a resist resin while suppressing light absorption, the permeability of the entire thick resist film having a thickness of 5 to 50 μm is improved. As a result, it is considered that the exposure energy can be suppressed, the difference in light amount between the upper part and the bottom part of the film can be suppressed, the diffusion of the acid into the film upper part of the unexposed region can be suppressed, and the scooped-out shape is hardly formed.

The formula (A-1) is as follows:

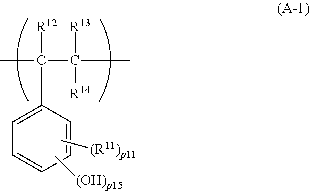

where,
R¹¹ is each independently C₁₋₅ alkyl (in which —CH₂— in the alkyl can be replaced with —O—); preferably methyl or ethyl; more preferably methyl. In the present invention, the expression “—CH₂— in the alkyl can be replaced with —O—” means that oxy can be present between carbon atoms in the alkyl, and it is not intended that the terminal carbon in the alkyl becomes oxy, i.e., it is not intended to have alkoxy or hydroxy.
R¹², R¹³, and R¹⁴ are each independently hydrogen, C₁₋₅ alkyl, C₁₋₅ alkoxy or —COOH; preferably hydrogen or methyl; more preferably hydrogen.
p11 is 0 to 4; preferably 0 or 1; more preferably 0.
p15 is 1 to 2; preferably 1.
p11+p15≤5 is satisfied.

The formula (A-2) is as follows:

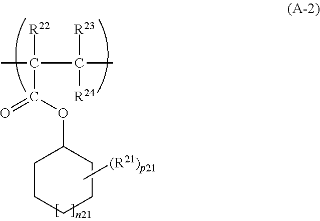

where,
R²¹ is each independently C₁₋₅ alkyl (in which methylene in the alkyl can be replaced with oxy); preferably methyl, ethyl or t-butyl; more preferably methyl or ethyl; further preferably methyl.
R²², R²³ and R²⁴ are each independently hydrogen, C₁₋₅ alkyl, C₁₋₅ alkoxy or —COOH; preferably hydrogen or methyl; more preferably hydrogen.
p21 is 0 to 1; preferably 0 or 1; more preferably 0.
n21 is 0 to 1; preferably 0 or 1; more preferably 1. When n21=0, it is a 5-membered ring, and when n=22, it is a 6-membered ring.

Exemplified embodiments of the formula (A-2) include the followings.

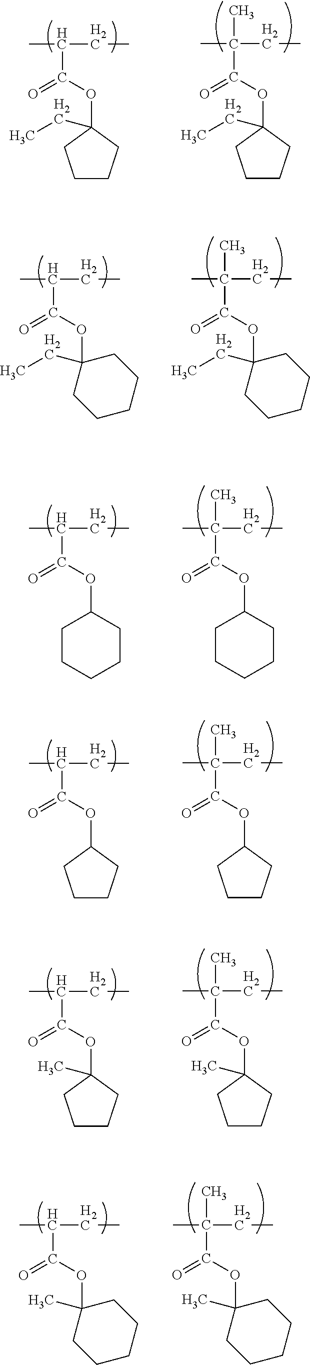

The formula (A-3) is as follows:

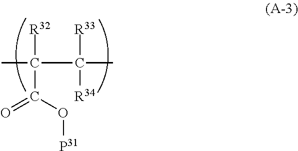

where
R³², R³³, and R³⁴ are each independently hydrogen, C₁₋₅ alkyl, C₁₋₅ alkoxy or —COOH; preferably hydrogen, methyl, ethyl, t-butyl, methoxy, t-butoxy or —COOH; more preferably hydrogen or methyl; further preferably hydrogen.
P³¹ is C₄₋₂₀ alkyl, the alkyl does not form a ring, and all or part of H in the alkyl can be substituted with halogen. The alkyl moiety of P³¹ is preferably branched. When the C₄₋₂₀ alkyl in P³¹ is substituted with halogen, it is preferable that all are replaced, and the halogen that replaces is preferably F or Cl; more preferably F. It is a preferred embodiment of the present invention that H of the C₄₋₂₀ alkyl in P³¹ is not replaced with any halogen. P³¹ is preferably methyl, isopropyl, or t-butyl; more preferably t-butyl.

Exemplified embodiments of the formula (A-3) include the followings.

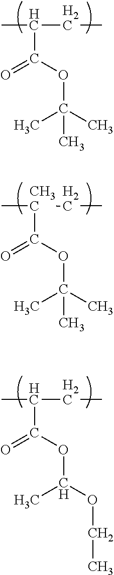

The formula (A-4) is as follows:

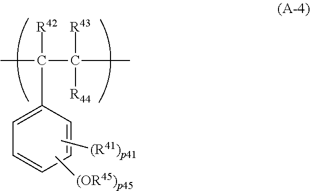

where
R⁴¹ is each independently C₁₋₅ alkyl (in which methylene in the alkyl can be replaced with oxy); preferably methyl, ethyl or t-butyl; more preferably methyl.
R⁴⁵ is each independently C₁₋₅ alkyl (in which methylene in the alkyl can be replaced with oxy); preferably methyl, t-butyl or —CH(CH₃)—O—CH₂CH₃.
R⁴², R⁴³, and R⁴⁴ are each independently hydrogen, C₁₋₅ alkyl, C₁₋₅ alkoxy or —COOH; preferably hydrogen or methyl; more preferably hydrogen.
p41 is 0 to 4; more preferably 0 or 1; further preferably 0.
p45 is 1 to 2; more preferably 1.
p41+p45≤5 is satisfied.

Exemplified embodiments of the formula (A-4) include the followings.

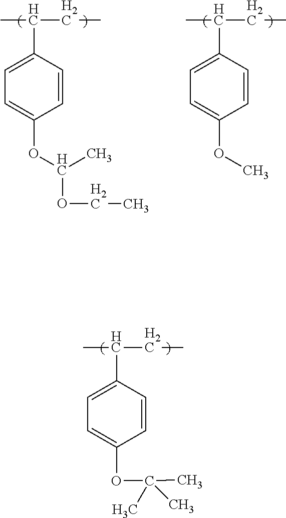

The alkali-soluble resin (A) can comprise plural kinds of repeating units represented by the formula (A-1), (A-2), (A-3) or (A-4). For example, it is possible for the alkali-soluble resin (A) to have a structural unit of p15=1 and a structural unit of p15=2 at a ratio of 1:1. In this case, it becomes p15=1.5 as a whole. Hereinafter, unless otherwise specified, the same applies to the numbers for representing polymer in the present invention.

In a preferred embodiment of the present invention, the alkali-soluble resin (A) comprises a repeating unit represented by the formula (A-1) and a repeating unit represented by the formula (A-3) in addition to the repeating unit represented by the formula (A-2).

These structural units are appropriately blended according to the purpose. It is a preferred embodiment that the structural units are blended so that an increase rate of solubility in the alkaline aqueous solution becomes appropriate by the acid.

n_{A-1}, n_{A-2}, n_{A-3} and n_{A-4}, which are the numbers of repeating units represented by the formulae (A-1), (A-2), (A-3) and (A-4) in the alkali-soluble resin (A), are described below.

n_{A-1}/(n_{A-1}+n_{A-2}+n_{A-3}+n_{A-4}) is 0 to 80 mass %; preferably 40 to 80%; more preferably 45 to 75%, further preferably 50 to 70%; and further more preferably 55 to 65%.

n_{A-2}/(n_{A-1}+n_{A-2}+n_{A-3}+n_{A-4}) is preferably 1 to 40%; more preferably 0 to 35%; further preferably 5 to 35%; and further more preferably 15 to 25%.

n_{A-3}/(n_{A-1}+n_{A-2}+n_{A-3}+n_{A-4}) is preferably 0 to 40%; more preferably 10 to 40%; further preferably 15 to 30%; and further more preferably 15 to 25%.

n_{A-4}/(n_{A-1}+n_{A-2}+n_{A-3}+n_{A-4}) is preferably 0 to 40%; more preferably 0 to 30%; further preferably 0 to 10%; and further more preferably 0 to 5%.

At least one of n_{A-3}/(n_{A-1}+n_{A-2}+n_{A-3}+n_{A-4}) and n_{A-4}/(n_{A-1}+n_{A-2}+n_{A-3}+n_{A-4}) is more than 0%. It is also a preferred embodiment of the present invention that n_{A-4} is 0.

As an embodiment of the present invention, n_{A-3}>0 and n_{A-4}=0.

The alkali-soluble resin (A) can also comprise additional repeating units other than the repeating units represented by the formulae (A-1), (A-2), (A-3) and (A-4).

nₜₒₜₐₗ, which is the total number of all repeating units included in the alkali-soluble resin (A), satisfies the following:

(n_{A-1}+n_{A-2}+n_{A-3}+n_{A-4})/nₜₒₜₐₗ=preferably 80 to 100%, more preferably 90 to 100%, and further preferably 95 to 100%. It is also a preferred embodiment of the alkali-soluble resin (A) to include no further repeating unit.

Exemplified embodiments of the alkali-soluble resin (A) includes the following:

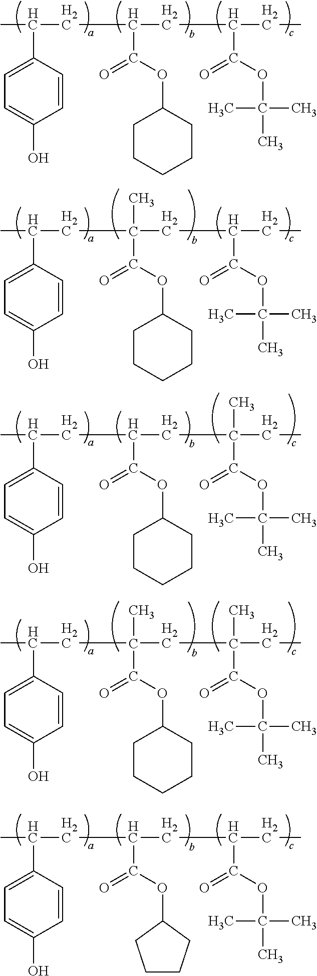

The mass average molecular weight (hereinafter sometimes referred to as Mw in some cases) of the alkali-soluble resin (A) is 10,000 to 50,000; more preferably 18,000 to 40,000; and further preferably 20,000 to 35,000.

In the present invention, Mw can be measured by gel permeation chromatography (GPC). In the measurement, it is a preferable example that a GPC column at 40 degrees Celsius, an elution solvent of tetrahydrofuran at 0.6 mL/min and monodisperse polystyrene as a standard are used.

The content of the component (A) is preferably more than 0 mass % and 50 mass % or less, 15 to 50 mass %, more preferably 20 to 45 mass %, further preferably 30 to 40 mass %, based on the composition.

### (B) Photoacid Generator

The composition according to the present invention contains a photoacid generator (B). The component (B) releases an acid by light irradiation. Preferably, an acid derived from the component (B) acts on the component (A) to play a role of increasing the solubility of the component (A) in an alkaline aqueous solution. For example, when the component (A) has an acid group protected by a protecting group, the protecting group is made eliminated by the acid. The component (B) used in the composition according to the present invention can be selected from conventionally known ones.

By exposure, the component (B) releases an acid having an acid dissociation constant pKa (H₂O) of preferably −20 to 1.4; more preferably −16 to 1.4; further preferably −16 to 1.2; further more preferably −16 to 1.1.

The component (B) is preferably represented by the formula (B-1) or the formula (B-2).

The formula (B-1) is as follows:

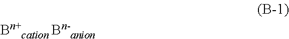

where,
Bⁿ⁺ cation is a cation represented by the formula (BC1), a cation represented by the formula (BC2), or a cation represented by the formula (BC3), Bⁿ⁺ cation is n valent as a whole, and n is 1 to 3, preferably 1 or 2, more preferably 1, and
Bⁿ⁻ anion is an anion represented by the formula (BA1), an anion represented by the formula (BA2), an anion represented by the formula (BA3), or an anion represented by the formula (BA4), and Bⁿ⁻ anion is n valent as a whole.

The formula (BC1) is as follows:

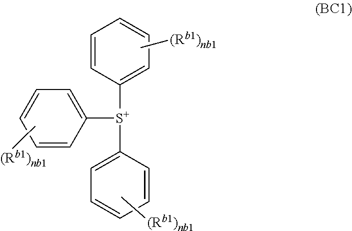

where,
R^{b1} is each independently C₁₋₆ alkyl, C₁₋₆ alkoxy, C₆₋₁₂ aryl, C₆₋₁₂ arylthio or C₆₋₁₂ aryloxy, preferably methyl, ethyl, t-butyl, methoxy, ethoxy, phenylthio or phenyloxy, more preferably t-butyl, methoxy, ethoxy, phenylthio or phenyloxy.
nb1 is each independently 0, 1, 2 or 3. It is also a preferred embodiment that all nb1 are 1 and all R^{b1} are identical. It is also a preferred embodiment that nb1 is 0.

Exemplified embodiments of the formula (BC1) are as follows.

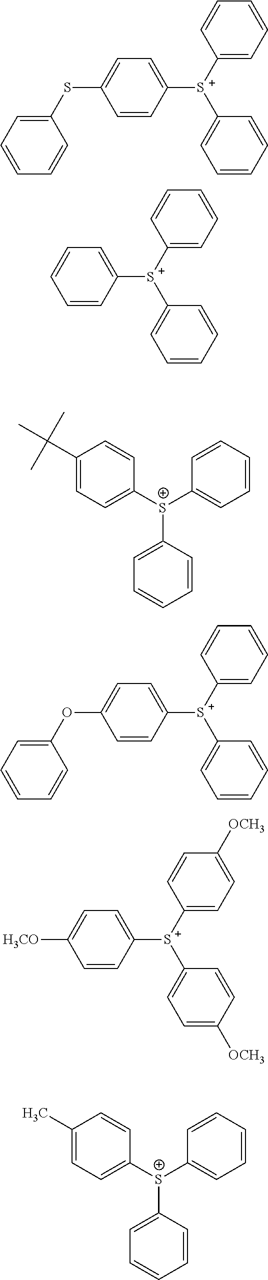 [SMILES: c1ccc(Sc2ccc([S+](c3ccccc3)c3ccccc3)cc2)cc1 ; c1ccc([S+](c2ccccc2)c2ccccc2)cc1 ; CC(C)(C)c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1 ; Cc1ccc([S+](c2ccccc2)c2ccccc2)cc1]

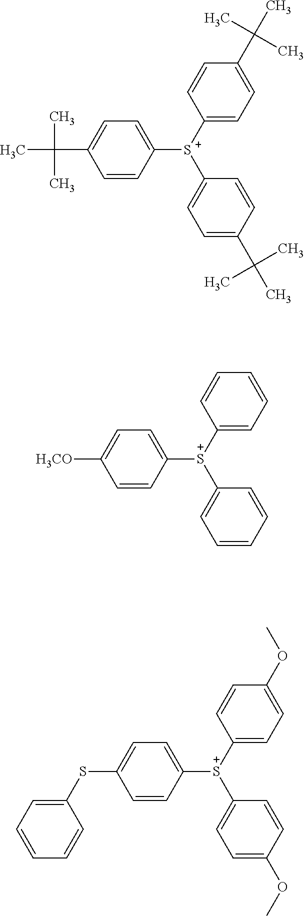 [SMILES: CC(C)(C)c1ccc([S+](c2ccc(C(C)(C)C)cc2)c2ccc(C(C)(C)C)cc2)cc1 ; COc1ccc([S+](c2ccccc2)c2ccccc2)cc1 ; COc1ccc([S+](c2ccc(OC)cc2)c2ccc(Sc3ccccc3)cc2)cc1]

The formula (BC2) is as follows:

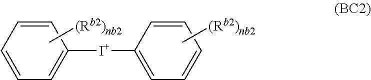

where,
R^{b2} is each independently C₁₋₆ alkyl, C₁₋₆ alkoxy or C₆₋₁₂ aryl, preferably alkyl having a C₄₋₆ branched structure, more preferably t-butyl or 1,1-dimethylpropyl, further more preferably t-butyl.
nb2 is each independently 0, 1, 2 or 3, preferably each 1.

Exemplified embodiments of the formula (BC2) are as follows.

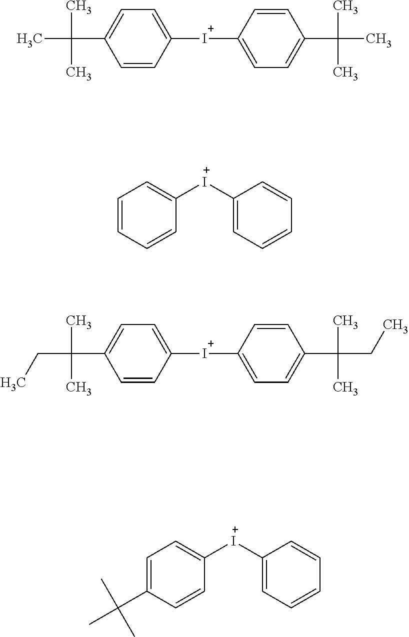

The formula (BC3) is as follows:

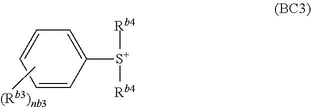

where,
R^{b3} is each independently C₁₋₆ alkyl, C₁₋₆ alkoxy or C₆₋₁₂ aryl, preferably methyl, ethyl, methoxy or ethoxy, more preferably methyl or methoxy.
R^{b4} is each independently C₁₋₆ alkyl, preferably methyl or ethyl, more preferably methyl.
nb3 is each independently 0, 1, 2 or 3; more preferably 3.

An exemplified embodiment of the formula (BC3) is as follows.

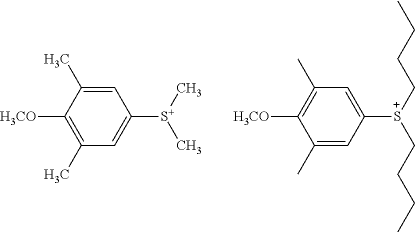 [SMILES: COc1c(C)cc([S+](C)C)cc1C ; CCCC[S+](CCCC)c1cc(C)c(OC)c(C)c1]

The Bⁿ⁺ cation selected from the group consisting of the cations represented by the formula (BC1) or (BC2) is preferable because it exhibits a better effect.

The formula (BA1) is as follows:

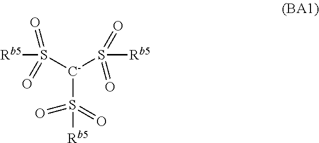

R^{b5} is each independently C₁₋₆ fluorine-substituted alkyl, C₁₋₆ fluorine-substituted alkoxy, or C₁₋₆ alkyl. For example, —CF₃ means that all of the hydrogen of methyl (C₁) are substituted with fluorine. Preferably all of the hydrogen present in the C₁₋₆ fluorine-substituted alkyl is substituted with fluorine. The alkyl moiety of R^{b5} is preferably methyl, ethyl, or t-butyl (more preferably methyl). In a preferred embodiment, R^{b5} is preferably a fluorine-substituted alkyl, more preferably —CF₃.

An exemplified embodiment of the formula (BA1) is as follows.

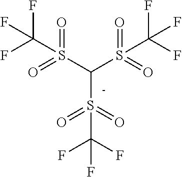 [SMILES: O=S(=O)(C(S(=O)(=O)C(F)(F)F)S(=O)(=O)C(F)(F)F)C(F)(F)F]

The formula (BA2) is as follows:

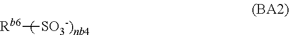

where,
R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, preferably C₂₋₆ fluorine-substituted alkyl, more preferably C₂₋₃ fluorine-substituted alkyl, further preferably C₃ fluorine-substituted alkyl. In the fluorine-substituted alkyl of R^{b6}, an embodiment in which all the hydrogen present in the alkyl moiety are substituted with fluorine is preferable. The alkyl moiety of R^{b6} is preferably methyl, ethyl, propyl, butyl or pentyl, more preferably propyl, butyl or pentyl; further preferably butyl. The alkyl moiety of R^{b6} is preferably linear.
nb4 is 1 or 2, preferably 1.

When nb4 is 2, R^{b6} becomes divalent, and hydrogen or fluorine becomes a single bond from R^{b6} described above and is bonded to an S atom.

Exemplified embodiments of the formula (BA2) are as follows.

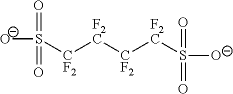 [SMILES: O=S(=O)([O-])C(F)(F)C(F)(F)C(F)(F)C(F)(F)S(=O)(=O)[O-]]

The formula (BA3) is as follows:

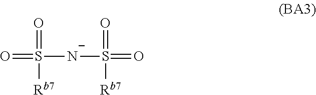

where,
R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, preferably C₂₋₆ fluorine-substituted alkyl. The alkyl moiety of R^{b7} is preferably methyl, ethyl, propyl, butyl, or pentyl, more preferably methyl, ethyl, or butyl, further preferably butyl. The alkyl moiety of R^{b7} is preferably linear.

Here, two R^{b7} can be bonded to each other to form a fluorine-substituted heterocyclic structure. In this case, the heterocycle can be monocyclic or polycyclic, but preferably is a monocyclic structure having 5 to 8 members.

Exemplified embodiments of the formula (BA3) are as follows.

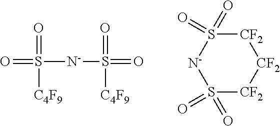

The formula (BA4) is as follows:

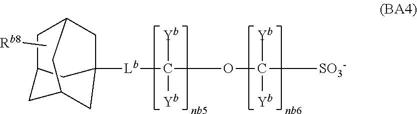

where,
R^{b8} is hydrogen, C₁₋₆ alkyl, C₁₋₆ alkoxy, or hydroxy, preferably hydrogen, methyl, ethyl, methoxy, or hydroxy, more preferably hydrogen or hydroxy.
L^{b} is carbonyl, oxy, or carbonyloxy, preferably carbonyl or carbonyloxy, more preferably carbonyl.
Y^{b} is each independently hydrogen or fluorine, and preferably, at least one or more thereof is fluorine.
nb5 is an integer of 0 to 10, preferably 0.
nb6 is an integer of 0 to 21, preferably 4, 5, or 6.

Exemplified embodiments of the formula (BA4) are as follows.

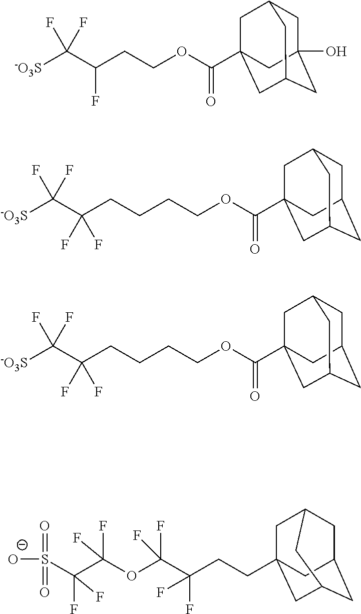

The formula (B-2) is as follows:

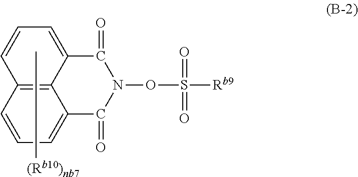

where,
R^{b9} is C₁₋₅ fluorine-substituted alkyl, preferably, C₁₋₄ alkyl in which all hydrogen are substituted with fluorine, more preferably C₁ or C₄ alkyl in which all hydrogen are substituted with fluorine.
R^{b10} is each independently C₃₋₁₀ alkenyl or alkynyl (where CH₃-in the alkenyl and alkynyl can be replaced with phenyl, and —CH₂— in the alkenyl and alkynyl can be replaced with at least one of —C(═O)—, —O— or phenylene), C₂₋₁₀ thioalkyl, C₅₋₁₀ saturated heterocycle, preferably C₃₋₁₂ alkenyl or alkynyl, or C₃₋₅ thioalkyl, C₅₋₆ saturated heterocycle; more preferably —C≡C—CH₂—CH₂—CH₂—CH₃, —CH═CH—C(═O)—O-tBu, —CH═CH-Ph, —S—CH(CH₃) 2, —CH═CH-Ph-O—CH(CH₃)(CH₂CH₃) and piperidine. Here, tBu means t-butyl and Ph means phenylene or phenyl. In the present invention, alkenyl means a monovalent group having one or more double bonds (preferably one). Similarly, alkynyl means a monovalent group having one or more triple bonds (preferably one).
nb7 is 0, 1 or 2, preferably 0 or 1, and more preferably 0. It is also a preferred embodiment that nb7=1 is satisfied.

Exemplified embodiments of the formula (B-2) include the followings.

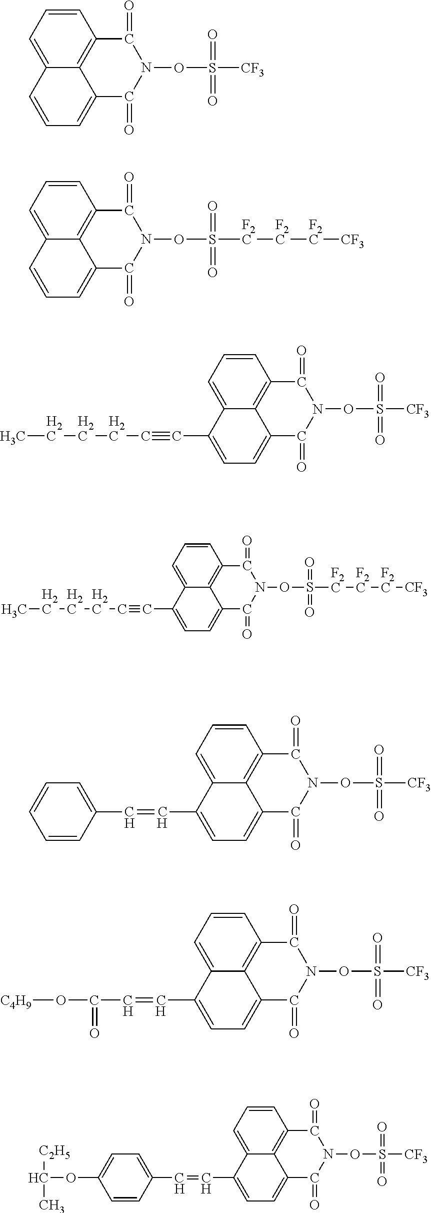

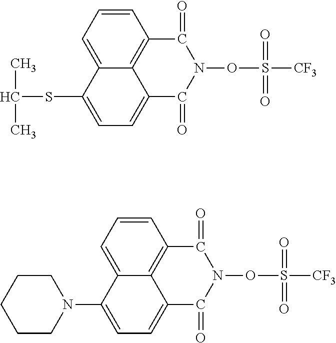 [SMILES: CC(C)Sc1ccc2c3c(cccc13)C(=O)N(OS(=O)(=O)C(F)(F)F)C2=O ; O=C1c2cccc3c(N4CCCCC4)ccc(c23)C(=O)N1OS(=O)(=O)C(F)(F)F]

The molecular weight of the photoacid generator (B) is preferably 400 to 2,500, more preferably 400 to 1,500.

The component (B) may be one or two or more kinds.

The content of the component (B) is preferably more than 0 mass % and 20 mass % or less, 0.05 to 10 mass %, more preferably 0.1 to 5 mass %, further preferably 0.5 to 2 mass %, based on the total mass of the component (A).

### (C) Solvent

The composition according to the present invention comprises a solvent (C).

The solvent (C) preferably contains propylene glycol monomethyl ether (PGME) (C-1), and the content of PGME (C-1) is preferably 30 to 100 mass %, more than 50 mass % and 100 mass % or less, preferably 55 to 90 mass %, and more preferably 55 to 80 mass %, based on the solvent (C).

The solvent (C) more preferably further contains a solvent (C-2) other than the solvent (C-1). The solvent (C-2) is selected from the group consisting of an alcohol solvent (C-2-1) and a low boiling point solvent (C-2-2). The alcohol solvent (C-2-1) is a compound in which a hydrogen atom of a chain or alicyclic hydrocarbon is replaced with hydroxy, and in which methylene can be replaced with oxy or carbonyl, and a hydrogen atom can be replaced with aryl.

The content of the solvent (C-2) is preferably 0 mass % or more and less than 50 mass %, preferably 5 to 45 mass %, and more preferably 10 to 35 mass %, based on the solvent (C).

The alcohol solvent (C-2-1) is, for example, selected from the group consisting of methanol, ethanol, n-propanol, i-propanol (isopropyl alcohol, IPA), n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethyl-1,3-hexanediol, diethylene glycol, dipropylene glycol, triethylene glycol, tripropylene glycol, glycerin, ethylene glycol monomethyl ether, ethylene glycol monoethyl ether, ethylene glycol mono-n-butyl ether, ethylene glycol mono-n-hexyl ether, ethylene glycol monophenyl ether, diethylene glycol monomethyl ether, diethylene glycol monoethyl ether, diethylene glycol mono-n-butyl ether, diethylene glycol mono-n-hexyl ether, ethoxytriglycol, propylene glycol monoethyl ether, propylene glycol monopropyl ether, propylene glycol monobutyl ether, dipropylene glycol monomethyl ether, dipropylene glycol monoethyl ether, dipropylene glycol mono propyl ether, dipropylene glycol monobutyl ether, tripropylene glycol monomethyl ether, 4-methyl-2-pentanol, 3-methyl-2-pentanol, 2-methyl-2-pentanol, 3-methyl-2-butanol, 2-methyl-2-butanol, 4-methyl-2-hexanol, 5-methyl-2-hexanol, 3-methyl-2-hexanol, 2-methyl-2-hexanol, ethyl lactate (EL), propyl lactate, n-butyl lactate, n-amyl lactate, butyric acid, methyl 2-hydroxyisobutyrate, methyl 2-hydroxybutyrate, methyl 3-hydroxybutyrate, methyl 4-hydroxybutyrate, ethyl 2-hydroxyisobutyrate, ethyl 2-hydroxybutyrate, ethyl 3-hydroxybutyric acid and ethyl 4-hydroxybutyrate; and is preferably IPA and/or EL.

The boiling point of the low boiling point solvent (C-2-2) at 1 atm is preferably 80 to 130° C., more preferably 80 to 110° C., and further preferably 80 to 100° C.

The low boiling point solvent (C-2-2) is, for example, selected from the group consisting of n-propanol, i-propanol (IPA), n-butanol, i-butanol, sec-butanol, t-butanol, i-pentanol, 2-methylbutanol, sec-pentanol, t-pentanol, ethylene glycol monomethyl ether, 2-methyl-2-pentanol, 3-methyl-2-butanol, 2-methyl-2-butanol, propylene glycol dimethyl ether, butyl acetate, methyl ethyl ketone, and methyl isobutyl ketone, and is preferably IPA and/or propylene glycol dimethyl ether.

The solvent (C) can further contain a solvent (C-3) other than the solvent (C-1) and the solvent (C-2). Examples of the solvent (C-3) include propylene glycol monomethyl ether acetate (PGMEA) and N-methylpyrrolidone.

The content of the solvent (C-3) is less than 50 mass %, preferably 0 mass % or more and 35 mass % or less, more preferably 0 mass % or more and 10 mass % or less, and further preferably 0 mass % or more and 5 mass % or less, based on the solvent (C). It is also a preferred embodiment of the present invention that the composition contains no solvent (C-3).

In a preferred embodiment of the present invention, the solvent (C) is PGME which is a low boiling point solvent. In a more preferred embodiment, the solvent (C) further contains a solvent (C-2) selected from the group consisting of an alcohol solvent (C-2-1) and a low boiling point solvent (C-2-2).

The content of the solvent (C) is preferably 20 mass % or more and less than 100 mass %, more preferably 50 to 79 mass %, further preferably 55 to 70 mass %, based on the composition.

### (D) Photoreactive Quencher

The composition according to the present invention can further contain a photoreactive quencher (D). The photoreactive quencher releases an acid by light irradiation, but the acid does not act directly on the polymer. In this respect, the photoreactive quencher is different from the component (B) having a direct action on the polymer by eliminating the protecting group of the polymer by the released acid.

The cationic moiety generated by the photoreactive quencher (D) receiving light preferably reacts with the anionic moiety generated by the photoacid generator (B) receiving light.

The photoreactive quencher (D) functions as a quencher that suppresses diffusion of an acid derived from the component (B) generated in the exposed region. This is not bound by theory, but is considered to be the following mechanism. By exposure, an acid is released from the component (B), and when this acid diffuses into an unexposed region (a region not exposed), salt exchange occurs with the component (D). That is, the anion of the component (B) and the cation of the component (D) become salts. This suppresses the diffusion of the acid. At this time, the anion of the component (D) is released, but this is a weak acid and cannot deprotect the polymer, so that it is considered that the unexposed region is not affected.

The photoreactive quencher (D) is preferably represented by the formula (D-1).

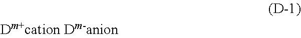

where,
the D^{m+} cation is a cation represented by the formula (DC1) or a cation represented by the formula (DC2), the D^{m+} cation as a whole is m-valent, and
m is 1 to 3, and
the D^{m-} anion is an anion represented by the formula (DA1) or an anion represented by the formula (DA2), and the D^{m-} anion as a whole is m-valent.
m is preferably 1 or 2, more preferably 1.

The formula (DC1) is as follows:

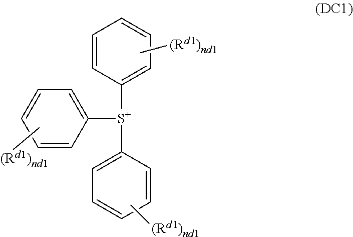

where,
R^{d1} is each independently C₁₋₆ alkyl, C₁₋₆ alkoxy, or C₆₋₁₂ aryl, C₆₋₁₂ arylthio or C₆₋₁₂ aryloxy, preferably methyl, ethyl, t-butyl, methoxy, ethoxy, phenylthio, or phenyloxy, more preferably t-butyl, methoxy, ethoxy, phenylthio, or phenyloxy, and further preferably t-butyl or methoxy.
nd1 is each independently 0, 1, 2 or 3. It is also a preferred embodiment that all nd1 are 1 and all R^{d1} are identical.

It is also a preferred embodiment that nd1 is 0.

Exemplified embodiments of the formula (DC1) are as follows:

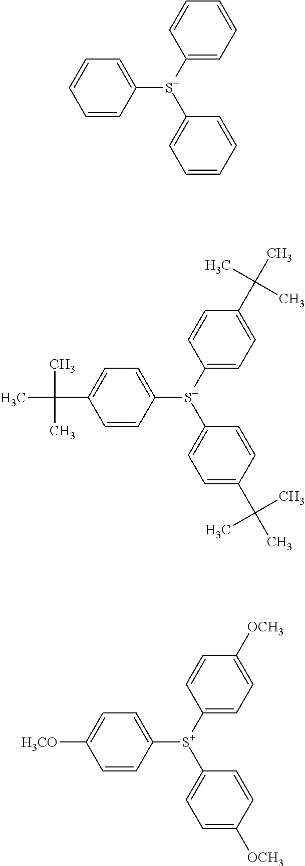 [SMILES: c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccc(OC)cc2)c2ccc(OC)cc2)cc1]

The formula (DC2) is as follows:

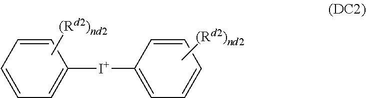

where,
R^{d2} is each independently C₁₋₆ alkyl, C₁₋₆ alkoxy or C₆₋₁₂ aryl. R^{d2} is preferably alkyl having a C₄₋₆ branched structure. Each R^{d2} can be identical to or different from each other, and it is more preferable that they are identical. R^{d2} is further preferably t-butyl or 1,1-dimethylpropyl, further more preferably t-butyl.
nd2 is each independently 0, 1, 2 or 3, preferably each 1.

Exemplified embodiments of the formula (DC2) are as follows:

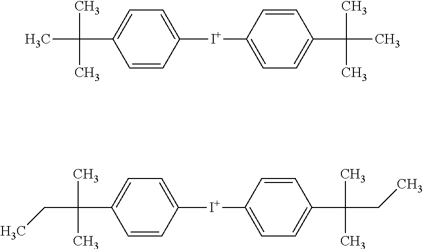

The formula (DA1) is as follows:

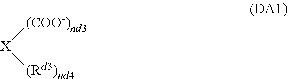

where,
X is C₁₋₂₀ hydrocarbon or a single bond. When X is hydrocarbon, X may be linear, branched, or cyclic, but is preferably linear or cyclic. X is preferably linear or cyclic. In the case of linear, it is preferably C₁₋₄ (more preferably C₁₋₂), and preferably has one double bond in the chain or is saturated. When it is cyclic, it can be monocyclic aromatic ring, or a saturated monocyclic or polycyclic ring. When it is monocyclic, it is preferably a 6-membered ring, and when it is polycyclic, it is preferably an adamantane ring. X is preferably methyl, ethyl, propyl, butyl, ethane, phenyl, cyclohexane, adamantane, or a single bond, more preferably methyl, phenyl, cyclohexane, or a single bond, and further preferably phenyl.
R^{d3} is each independently hydrogen, hydroxy, carboxy, C₁₋₆ alkyl, or C₆₋₁₀ aryl, preferably hydroxy, methyl, ethyl, 1-propyl, 2-propyl, t-butyl, or phenyl, and more preferably hydroxy.
nd3 is 1, 2 or 3, preferably 1 or 2, and more preferably 1.
nd4 is 0, 1 or 2, preferably 0 or 1, and more preferably 1.

When X is a single bond, R^{d3} is preferably hydrogen. (DA1) in which X is a single bond, R^{d3} is hydrogen, and nd3=nd4=1 represents an anion that is H—COO⁻.

Exemplified embodiments of the formula (DA1) are as follows.

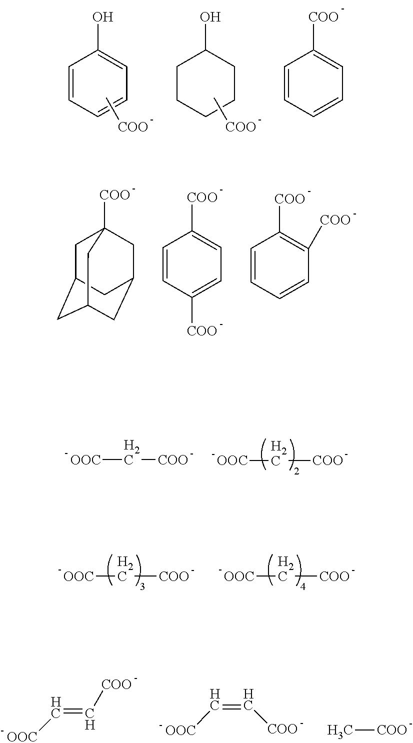

The formula (DA2) is as follows:

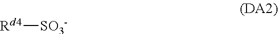

where,
R^{d4} is C₁₋₁₅ alkyl (in which all or part of the alkyl can form a ring, and —CH₂— in the alkyl can be replaced with —C(═O)—). R^{d4} is preferably C₃₋₁₃ alkyl; more preferably C₅₋₁₂ alkyl; further preferably C₈₋₁₇ alkyl; further more preferably C₁₀ alkyl. Preferably, all or part of the alkyl of R^{d4} forms a ring; more preferably, part of the alkyl of R^{d4} forms a ring. Preferably, one or more (more preferably one) of —CH₂— in the alkyl of R^{d4} are replaced with —C(═O)—.

Exemplified embodiments of the formula (DA2) include the followings.

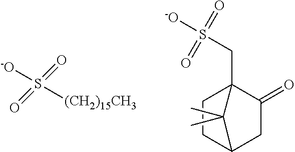

The photoreactive quencher (D) releases an acid with an acid dissociation constant pKa (H₂O) of preferably 1.5 to 8; more preferably 1.5 to 5 by exposure.

The molecular weight of the photoreactive quencher (D) is preferably 300 to 1,400; more preferably 300 to 1,200.

The content of the photoreactive quencher (D) is preferably 0.01 to 5 mass %; more preferably 0.03 to 1 mass %; and further preferably 0.05 to 1 mass %, based on the component (A).

### (E) Surfactant

The composition according to the present invention can further contain a surfactant (E). By the component (E), the coatability of the composition can be improved. Examples of the component (E) include nonionic surfactants, anionic surfactants, amphoteric surfactants and the like.

Examples of the nonionic surfactant include, polyoxyethylene alkyl ethers such as polyoxyethylene lauryl ether, polyoxyethylene oleyl ether and polyoxyethylene cetyl ether, polyoxyethylene fatty acid diesters, polyoxyethylene fatty acid monoesters, polyoxyethylene polyoxypropylene block polymer, acetylene alcohol, acetylene glycol, polyethoxylate of acetylene alcohol, acetylene glycol derivatives such as polyethoxylate of acetylene glycol, fluorine-containing surfactants, for example, FLUORAD (trade name, 3M Japan), MEGAFACE (trade name: DIC), SURFLON (trade name, AGC), or organosiloxane surfactants, for example, KF-53 (trade name, Shin-Etsu Chemical), BYK-333 (trade name, BYK), and the like. Examples of the acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexanediol, and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Examples of the amphoteric surfactant include 2-alkyl-N-carboxymethyl-N-hydroxyethyl imidazolium betaine, lauric acid amide propyl hydroxysulfone betaine, and the like.

The component (E) may be one or two or more kinds.

The content of the component (E) is preferably 0.0001 to 1 mass %, more preferably 0.001 to 1 mass %, and further preferably 0.05 to 0.5 mass %, based on the component (A).

### (F) Plasticizer

The composition according to the present invention can further contain a plasticizer (F). By containing the component (F), film cracking during thick film formation can be suppressed.

Examples of the component (F) include an alkali-soluble vinyl polymer and an acid-dissociable group-containing vinyl polymer. Exemplified embodiments thereof include polyvinyl chloride, polystyrene, polyhydroxystyrene, polyvinyl acetate, polyvinyl benzoate, polyvinyl ether, polyvinyl butyral, polyvinyl alcohol, polyether ester, polyvinyl pyrrolidone, polyacrylic acid, polymethacrylic acid, polyacrylic acid ester, polyimide maleate, polyacrylamide, polyacrylonitrile, polyvinyl phenol, novolac, and copolymers thereof, and polyvinyl ether, polyvinyl butyral, and polyether ester are more preferable.

The content of the component (F) is 0 to 3 mass %, and more preferably 0 to 1 mass %, based on the composition. It is also a preferred embodiment of the present invention that the composition of the present invention contains no component (F).

### (G) Additive

The composition according to the present invention can comprise an additive (G) other than (A) to (F). The component (G) is selected from at least one of the group consisting of a surface smoothing agent, a dye, a contrast enhancer, a base, an acid, a radical generator, a substrate adhesion enhancer and an antifoaming agent.

The content of the component (G) (the sum in the case of a plurality of components (G)) is preferably 0.0001 to 10 mass % and more preferably 0.01 to 2 mass %, based on the component (A). It is also a preferred embodiment of the present invention that no component (G) is contained (0 mass %).

The base can be expected to have an effect of suppressing the diffusion of the acid generated in the exposed region and an effect of suppressing the acid deactivation of the film surface by the amine component contained in the air. The base is preferably ammonia, C₁₋₁₆ primary aliphatic amine compounds, C₂₋₃₂ secondary aliphatic amine compounds, C₃₋₄₈ tertiary aliphatic amine compounds, C₆₋₃₀ aromatic amine compounds, or C₅₋₃₀ heterocyclic amine compounds.

Examples of the C₁₋₁₆ primary aliphatic amine compounds include methylamine, ethylamine, isopropylamine, tert-butylamine, cyclohexylamine, ethylenediamine, and tetraethylenediamine.

Examples of the C₂₋₃₂ secondary aliphatic amine compounds include dimethylamine, diethylamine, methylethylamine, dicyclohexylamine and N,N-dimethylmethylenediamine.

Examples of the C₃₋₄₈ tertiary aliphatic amine compounds include trimethylamine, triethylamine, dimethylethylamine, triisobutylamine, triethanolamine, tri-n-octylamine, tricyclohexylamine, N,N,N′,N′-tetramethylethylenediamine, N,N,N′,N″,N″-pentamethyldiethylenetriamine, tris[2-(dimethylamino)ethyl]amine, and tris[2-(2-methoxyethoxy)ethyl]amine.

Examples of the C₆₋₃₀ aromatic amine compounds include aniline, benzylamine, naphthylamine, N-methylaniline, 2-methylaniline, 4-aminobenzoic acid, and phenylalanine.

Examples of the C₅₋₃₀ heterocyclic amine compounds include pyrrole, oxazole, thiazole, imidazole, 4-methylimidazole, pyridine, methylpyridine, butylpyridine, and 1,4-diazabicyclo[2.2.2]octane.

### Method for Manufacturing a Resist Film

The method for manufacturing a resist film according to the present invention comprises the following steps:
(1) applying the composition according to the present invention above a substrate; and
(2) heating the composition to form a resist film.

Hereinafter, one embodiment of the manufacturing method according to the present invention is described.

### Step (1)

The composition according to the present invention is applied above a substrate (for example, a silicon/silicon dioxide coated substrate, a silicon nitride substrate, a silicon wafer substrate, a glass substrate, an ITO substrate, and the like) by an appropriate method. In the present invention, the “above” includes the case where a layer is formed directly on a substrate and the case where a layer is formed on a substrate via another layer. For example, a planarization film or resist underlayer can be formed immediately above a substrate, and the composition according to the present invention can be applied immediately above the film. An embodiment in which the composition according to the present invention is applied immediately above a substrate (without intervening other layer) is more preferable. The application method is not particularly limited, and examples thereof include a method using a spinner or a coater.

### Step (2)

After application of the composition, a resist film is formed by heating (prebaking). The heating in the step (2) is performed, for example, by a hot plate. The heating temperature is preferably 100 to 250° C. (more preferably 100 to 200° C.; further preferably 100 to 160° C.). The temperature here is a temperature of heating atmosphere, for example, that of a heating surface of a hot plate. The heating time is preferably 30 to 300 seconds (more preferably 60 to 240 seconds). The heating is preferably performed in an air or a nitrogen gas atmosphere.

The film thickness of the resist film is selected depending on the purpose, but when the composition according to the present invention is used, a pattern having a better shape can be obtained when a coating film having thick film thickness is formed. For this reason, the thickness of the resist film is preferably thicker, for example, preferably 5.0 to 50 μm, more preferably 11.0 to 30 μm, further preferably 11.0 to 25 μm, further more preferably 11 to 20 μm.

A resist pattern can be manufactured by the method further comprising the following steps:
(3) exposing the resist film; and
(4) developing the resist film. Although describing for clarity, the steps (1) and (2) are performed before the step (3). The numbers in parentheses indicating the step mean the order. The same applies hereinafter.

### Step (3)

The resist film is exposed through a predetermined mask. The wavelength of light to be used for exposure is not particularly limited, but it is preferable to expose with light having a wavelength of 13.5 to 248 nm. In particular, KrF excimer laser (wavelength: 248 nm), ArF excimer laser (wavelength: 193 nm), extreme ultraviolet ray (wavelength: 13.5 nm), or the like can be used, and KrF excimer laser is preferable. These wavelengths allow a range of #1%. After exposure, post exposure bake (PEB) can also be performed, as necessary. The post exposure baking temperature is preferably 80 to 150° C., more preferably 100 to 140° C., and the heating time is 0.3 to 5 minutes, preferably 0.5 to 3 minutes.

### Step (4)

The exposed resist film is developed with a developer. As the developing method, a method conventionally used for developing a photoresist, such as a paddle developing method, an immersion developing method, or a swinging immersion developing method, can be used. As the developer, aqueous solution containing inorganic alkalis, such as sodium hydroxide, potassium hydroxide, sodium carbonate and sodium silicate; organic amines, such as ammonia, ethylamine, propylamine, diethylamine, diethylaminoethanol and triethylamine; quaternary amines, such as tetramethylammonium hydroxide (TMAH); and the like are used, and a 2.38 mass % TMAH aqueous solution is preferable. A surfactant can be further added to the developer. The temperature of the developer is preferably 5 to 50° C., more preferably 25 to 40° C., and the development time is preferably 10 to 300 seconds, more preferably 30 to 60 seconds. After development, washing with water or rinsing treatment can also be performed, as necessary. When a positive type resist composition is used, the exposed region is removed by development to form a resist pattern. The resist pattern can also be further made finer, for example, using a shrink material.

When a thick film resist pattern is formed using a chemically amplified resist, a scooped-out area may be generated at the top of resist pattern wall, especially when the aspect ratio is high (details of the scooped-out area are explained using Figures in Examples).

In a preferred embodiment, a ratio of the distance between the perpendicular line drawn from the end point of the top of the resist pattern down to the substrate and the perpendicular line drawn from the most scooped point on the side surface of the resist pattern down to the substrate (hereinafter sometimes referred to as the width of bite) to the resist film thickness is 0.023 or less, more preferably 0 to 0.022, further preferably 0 to 0.021. In the present invention, the scooped-out area can be suppressed. Since the scooped-out area can be suppressed, resistance of the pattern can be strengthened in the subsequent steps, which is advantageous.

A processed substrate can be manufactured by a method further comprising the following step:
(5) processing using the resist pattern as a mask.

### Step (5)

The formed resist pattern is preferably used for processing an underlayer or a substrate (more preferably a substrate). In particular, with the resist pattern as a mask, various substrates that become a base can be processed using a dry etching method, a wet etching method, an ion implantation method, a metal plating method, or the like. It is a more preferable embodiment to etch the substrate by a dry etching method using the resist pattern of the present invention as a mask. Since the resist pattern according to the present invention can increase the film thickness, it can also be used for substrate processing using an ion implantation method.

When processing an underlayer using a resist pattern, the processing can be performed in stages. For example, a BARC layer can be processed using a resist pattern, a SOC film can be processed using the BARC pattern, and a substrate can be processed using the SOC pattern.

As an example of a processing method, there is mentioned a method including:
(5a) etching the resist pattern; and
(5b) etching the substrate.

A combination of the steps (5a) and (5b) is repeated at least twice or more; and
the substrate includes a laminate of a plurality of Si-containing layers, in which at least one Si-containing layer is conductive and at least one Si-containing layer is electrically insulative.

Preferably, the conductive Si-containing layers and electrically insulative Si-containing layers are alternately laminated.

The resist pattern according to the present invention can also be used for ion implantation.

Therefore, the method for manufacturing a processed substrate according to the present invention includes steps below:
manufacturing a resist pattern by the method according to claim 11; and
performing ion implantation using the resist pattern as a mask, or
processing an underlayer of the resist pattern using the resist pattern as a mask to form an underlayer pattern, and performing ion implantation using the underlayer pattern as a mask.

The ion implantation can be performed by a known method using a known ion implantation apparatus. In the manufacture of semiconductor devices, liquid crystal display devices and the like, forming an impurity diffusion layer on a substrate surface is conducted. The formation of an impurity diffusion layer is usually performed in two stages of impurity introduction and diffusion thereof. As one method of the introduction, there is an ion implantation in which impurities such as phosphorus and boron are ionized in a vacuum, accelerated in a high electric field and implanted into the support surface. As the ion acceleration energy during ion implantation, an energy load of 10 to 200 keV is generally applied to the resist pattern, which may destroy the resist pattern.

Since the resist pattern formed according to the present invention is a thick film, has high rectangularity, and has high heat resistance, the resist pattern can be suitably used for ion implantation applications in which ions are implanted at high energy.

Ion sources (impurity elements) include ions such as boron, phosphorus, arsenic, and argon. Thin films on substrates include silicon, silicon dioxide, silicon nitride, aluminum, and the like.

Thereafter, if necessary, the substrate is further processed, a step of forming a wiring on the processed substrate is preferably conducted, and a device can be manufactured. For these processing, known methods can be applied. If necessary, the substrate is cut into chips, which are connected to a lead frame and packaged with resin. In the present invention, this packaged product is referred to as the device. Examples of the device include a semiconductor device, a liquid crystal display device, an organic EL display device, a plasma display device, and a solar cell device, preferably a semiconductor.

### EXAMPLE

The present invention is described below with reference to several examples. The embodiment of the present invention is not limited only to these examples.

### Preparation of Resist Composition I

PGME, PGMEA, and MMPOM (propylene glycol dimethyl ether) are mixed at a mass ratio of 60:20:20 (=PGME:PGMEA:MMPOM) to obtain a mixed solvent. The alkali-soluble resin A1, the photoacid generator B1, the photoreactive quencher D1, and the surfactant E1 are added to this mixed solvent to obtain a mixed solution. The solid component concentration is 36.5 mass %. These are A1:B1:D1:E1=100:1.44:0.10:0.15 in terms of mass ratio.

In the following Examples, components other than the solvent are referred to as solid components, and the concentration of the sum of components other than the solvent in the entire composition is referred to as solid component concentration.

The mixed solution is stirred at room temperature for 30 minutes to obtain a solution. It is visually confirmed that each component is completely dissolved. The obtained solution is filtered through a 0.05 μm filter to obtain Resist Composition I.
Alkali-soluble resin A1: p-hydroxystyrene/cyclohexane acrylate/t-butyl acrylate copolymer (Mw=27,000, random copolymerization)

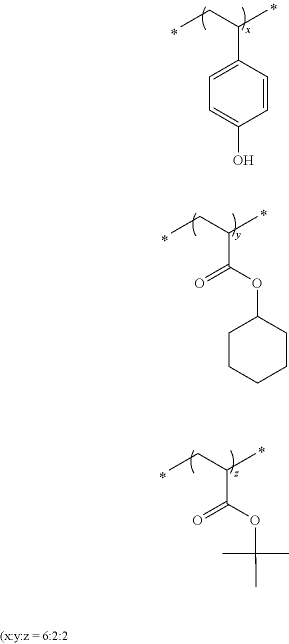

Photoacid generator B1: the compound shown below (Heraeus, DTBPIO-C1)

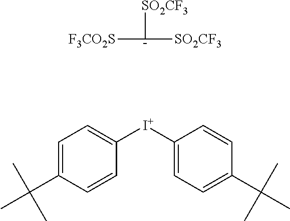

Photoreactive quencher D1: the compound shown below (Sumitomo Pharma Food & Chemical Co., Ltd., ZK-1741)

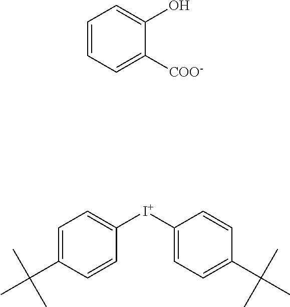

Surfactant E1: organosiloxane surfactant (BYK, BYK-333)

### Preparation of Comparative Resist Composition II

Comparative Resist Composition II is obtained in the same manner as in the preparation of Resist Composition I, except that the alkali-soluble resin A1 is changed to the alkali-soluble resin A2.
Alkali-soluble resin A2: p-hydroxystyrene/styrene/t-butyl acrylate copolymer (Mw=27,000, random copolymerization)

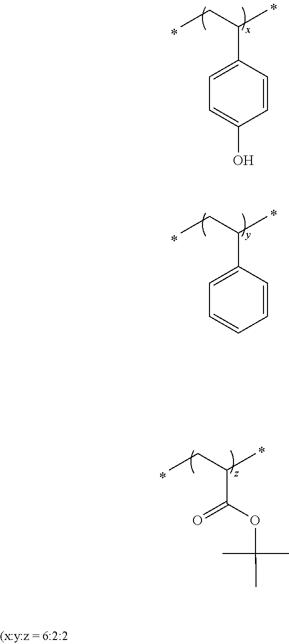

### <Formation of Resist Film>

An 8-inch silicon wafer is subjected to an HMDS treatment at 90° C. for 60 seconds. Using the coater developer Mark8 (Tokyo Electron), the prepared resist solution is added dropwise and coated by spinning on the 8-inch silicon wafer. The rotation speed of spin coating is changed from 1,000 rpm to 3,000 rpm according to a target film thickness. Baking is performed using a hot plate at 140° C. for 120 seconds to obtain a resist film. The film thickness of the obtained resist film is measured using a light-interference film thickness meter (M-1210, SCREEN).

The film thickness of the resist film obtained by performing the above operation and spin-coating Resist Composition I (solid component concentration: 36.5 mass %) at 1,000 rpm is 18.0 μm. In the following Examples, the rotation speed of spin coating is adjusted according to a target film thickness to be obtained a desired film thickness.

In the case of forming a resist film having a film thickness of 10 to 18 μm, Composition 1 having a solid component concentration of 36.5 mass % is used. The rotation speed of spin coating is 1,000 rpm for a film thickness of 18 μm and 3,000 rpm for a film thickness of 10 μm. By gradually increasing the rotation speed, the film thickness to be obtained can be gradually reduced.

Table 1 shows the results (Example 101 and Comparative Example 101) when Resist Composition I or Comparative Resist Composition II is used and the film thickness is 18 μm.

Table 2 shows the results (Example 201 and Comparative Example 201) when Resist Composition I or Comparative Resist Composition II is used and the film thickness is 10 μm.

Table 3 shows the results (Examples 301 to 303) when Resist Composition I is used and the film thicknesses are 12 μm, 14 μm, and 16 μm.

TABLE 1

| | | Film | | Width | | | | | Etching | Etching |
|---|---|---|---|---|---|---|---|---|---|---|
| | Resist | Thickness | Sensitivity | of bite | | | DoF | Film | Rate | Rate |
| | Composition | (μm) | (mJ/cm²) | (nm) | Rectangularity | EL | (μm) | loss | (O₂) | (CF₄) |
| Example | Resist | 18 | 222 | 370 | 1.79 | 8.8% | 2.0 | <20 nm | 495 | 163 |
| 101 | Composition | | | | | | | | nm/min | nm/min |
| | I | | | | | | | | | |
| Comparative | Comparative | 18 | 525 | 1,303 | 2.05 | 7.6% | 1.7 | <20 nm | 478 | 154 |
| Example | Resist | | | | | | | | nm/min | nm/min |
| 101 | Composition | | | | | | | | | |
| | II | | | | | | | | | |

TABLE 2

| | | Film | | Width | | | | | Etching | Etching |
|---|---|---|---|---|---|---|---|---|---|---|
| | Resist | Thickness | Sensitivity | of bite | | | DoF | Film | Rate | Rate |
| | Composition | (μm) | (mJ/cm²) | (nm) | Rectangularity | EL | (μm) | loss | (O₂) | (CF₄) |
| Example | Resist | 10 | 96 | 185 | 1.36 | 39.1% | 1.1 | <20 nm | 495 | 163 |
| 201 | Composition | | | | | | | | nm/min | nm/min |
| | I | | | | | | | | | |
| Comparative | Comparative | 10 | 179 | 245 | 1.47 | 38.7% | 0.9 | <20 nm | 478 | 154 |
| Example | Resist | | | | | | | | nm/min | nm/min |
| 201 | Composition | | | | | | | | | |
| | II | | | | | | | | | |

TABLE 3

| | | Film | | Width | | | | | Etching | Etching |
|---|---|---|---|---|---|---|---|---|---|---|
| | Resist | Thickness | Sensitivity | of bite | | | DoF | Film | Rate | Rate |
| | Composition | (μm) | (mJ/cm²) | (nm) | Rectangularity | EL | (μm) | loss | (O₂) | (CF₄) |
| Example | Resist | 12 | 109 | 245 | 1.46 | 30.6% | 1.2 | <20 nm | 495 | 163 |
| 301 | Composition | | | | | | | | nm/min | nm/min |
| | I | | | | | | | | | |
| Example | Resist | 14 | 129 | 258 | 1.53 | 18.4% | 1.3 | <20 nm | 495 | 163 |
| 302 | Composition | | | | | | | | nm/min | nm/min |
| | I | | | | | | | | | |
| Example | Resist | 16 | 168 | 304 | 1.67 | 14.0% | 1.6 | <20 nm | 495 | 163 |
| 303 | Composition | | | | | | | | nm/min | nm/min |
| | I | | | | | | | | | |

### <Formation of Resist Pattern>

In Example 101 and Comparative Example 101, the resist film having a film thickness of 18 μm obtained in the example of resist film formation is exposed using a KrF stepper (FPA3000-EX5, Canon Inc.). Thereafter, PEB (post exposure bake) is performed using a hot plate at 110° C. for 120 seconds. This film is developed with a 2.38 mass % TMAH aqueous solution for 90 seconds, and a trench pattern having Line:Space=3:1 and a space width of 10 μm is formed. The cross-sectional shape of the obtained pattern is observed using a scanning electron microscope (S9200, Hitachi) to confirm a pattern shape.

Using Resist Composition I, the operation is performed to form a resist film having a film thickness of 18 μm as in the example of resist pattern formation, thereby obtaining a resist pattern in which the width of the top of the pattern wall is 7 μm. The exposure amount at this time is defined as sensitivity.

In the case of forming a resist pattern from a resist film having another film thickness, exposure is performed under the same conditions as those for the resist film having a film thickness of 18 μm described above, thereby obtaining a resist pattern.

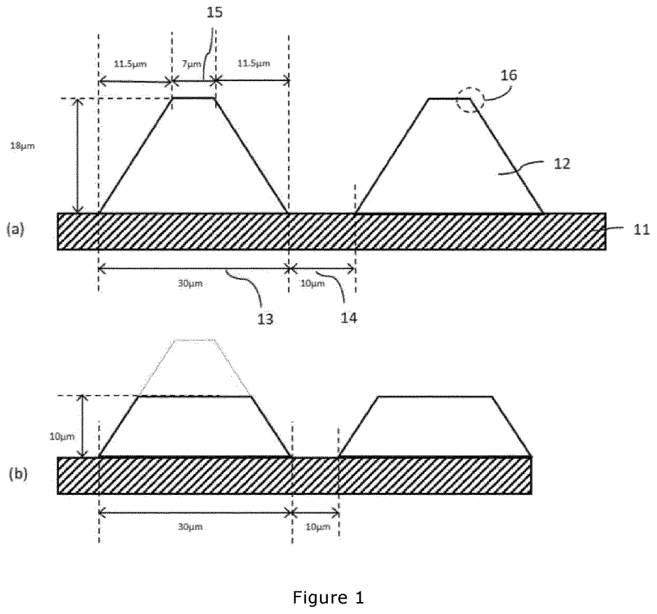

The pattern shape to be formed will be described with reference to FIGS. 1A and 1B. In FIG. 1A, a resist pattern 12 is formed on a substrate 11, and a line width 13, a space width 14, and a top width 15 are 15 μm, 5 μm, and 7 μm, respectively. A top of pattern wall 16 is an end of the top, and a scooped-out area may be generated at this portion. The resist film thickness of FIG. 1A is 18 μm. FIG. 1B is a schematic view when the film thickness is 10 μm without changing the inclination of the resist pattern.

In the evaluation in which the film thickness is changed, a pattern is manufactured without changing the inclination as described above.

### <Width of Bite>

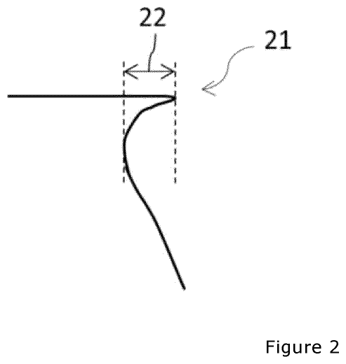

The formed resist pattern is observed, and the degree of being scooped inward from the top of the pattern (the width of bite) is evaluated. In particular, it is explained with reference to FIG. 2. FIG. 2 schematically shows the top of wall 21 of FIGS. 1A and 1B. A line is drawn perpendicularly from the end of the top of the pattern down to the substrate. A line is drawn perpendicularly from the most scooped point on the side surface of the pattern down to the substrate. The distance between each line is taken as the width of bite (nm).

### <Rectangularity>

When the width of the space at the top of the formed resist pattern is designated as Sₜ, and the width of the space at the bottom part of the resist pattern is designated as S_{b}, rectangularity is calculated as St/Sb.

St is measured at the top above a portion where a scooped-out area is generated.

### <Exposure Latitude (EL)>

The above exposure amount is defined as an optimum exposure amount (Eop), and exposure amounts (Emax, Emin) at which the width of the top of the pattern wall is +0.5% are measured.

$$Assuming that EL = ( ( E max - E min ) / E o p ) \times 100 ( \% ) ,$$

the EL is calculated.

### <Depth of Focus (DoF)>

When the focal position of an exposure machine is shifted from an optimum degree (Dop), focal positions at which the width of the top of the resist pattern wall is +0.5% (Dmax, Dmin) are measured.

$$Assuming that DoF = ( ( D max - D min ) / Dop ) \times 100 ( \% ) ,$$

the DoF is calculated.

### <Film Loss>

The film thicknesses before and after development are measured, the film loss=film thickness before development-film thickness after development is calculated.

### <Etching Rate>

The resist pattern obtained above is subjected to 02 etching or CF₄ etching, and then an etching rate is measured.

For etching, an etching apparatus NE-5000N (ULVAC) is used.

In O₂ etching, each film on the wafer is dry-etched at a chamber pressure of 10 Pa, a power of 500 W, a bias of 100 W, and a gas flow rate of O₂ (30 sccm), N₂ (5 sccm), and He (266 sccm) for 30 seconds.

In CF₄ etching, each film on the wafer is dry-etched at a chamber pressure of 10 Pa, a power of 500 W, a bias of 100 W, and a gas flow rate of CF₄ (45 sccm) and He (266 sccm) for 30 seconds.

In the film thickness measurement, the film thickness is measured using a light-interference film thickness meter (M-1210, SCREEN).

The film thickness before etching and the film thickness after etching are measured. A difference between the former and the latter is obtained, and an etching rate per unit time (nm/min) is calculated.

### EXPLANATION OF SYMBOLS

11. substrate
12. resist pattern
13. line width
14. space width
15. top width
16. top of pattern wall
21. top of wall
22. width of bite

1. A thick film chemically amplified positive type resist composition comprising an alkali-soluble resin (A), a photoacid generator (B) and a solvent (C):
wherein,
the film thickness of the resist film formed from the thick film chemically amplified positive type resist composition is 5.0 to 50.0 μm;
the alkali-soluble resin (A) comprises the following repeating units: 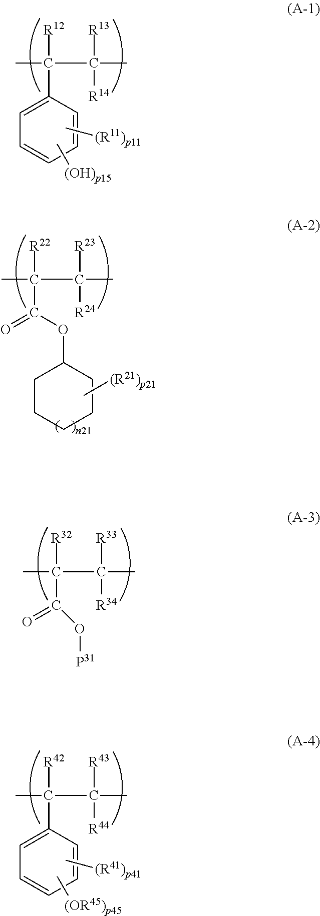
(where,
R¹¹, R²¹, R⁴¹ and R⁴⁵ are each independently C₁₋₅ alkyl (in which —CH₂— in the alkyl can be replaced with —O—);
R¹², R¹³, R¹⁴, R²², R²³, R²⁴, R³², R³³, R³⁴, R⁴², R⁴³ and R⁴⁴ are each independently hydrogen, C₁₋₅ alkyl, C₁₋₅ alkoxy or —COOH;
p11 is 0 to 4, p15 is 1 to 2, and p11+p15≤5;
p21 is 0 to 4;
n21 is 0 to 1;
p41 is 0 to 4, p45 is 1 to 2, and p41+p45≤5;
P³¹ is C₄₋₂₀ alkyl (in which the alkyl forms no ring, and all or part of H in the alkyl can be substituted with halogen)); and
n_{A-1}, n_{A-2}, n_{A-3} and n_{A-4}, which are the numbers of repeating units of the repeating units (A-1), (A-2), (A-3) and (A-4) in the alkali-soluble resin (A), satisfy the following:
$${n}_{A - 1} / ( {n}_{A - 1} + {n}_{A - 2} + {n}_{A - 3} + {n}_{A - 4} ) = 0 to 80 \% ,$$
$${n}_{A - 2} / ( {n}_{A - 1} + {n}_{A - 2} + {n}_{A - 3} + {n}_{A - 4} ) = 1 to 40 \% ,$$
$${n}_{A - 3} / ( {n}_{A - 1} + {n}_{A - 2} + {n}_{A - 3} + {n}_{A - 4} ) = 0 to 40 \% , or$$
$${n}_{A - 4} / ( {n}_{A - 1} + {n}_{A - 2} + {n}_{A - 3} + {n}_{A - 4} ) = 0 to 40 \% ;$$
wherein at least one of n_{A-3}/(n_{A-1}+n_{A-2}+n_{A-3}+n_{A-4}) and n_{A-4}/(n_{A-1}+n_{A-2}+n_{A-3}+n_{A-4}) is more than 0%; and
optionally, wherein nₜₒₜₐₗ, which is the total number of all repeating units contained in the alkali-soluble resin (A), satisfies the following:
$$( {n}_{A - 1} + {n}_{A - 2} + {n}_{A - 3} + {n}_{A - 4} ) / {n}_{total} = 80 to 100 \% .$$

2. The composition according to claim 1, wherein the solvent (C) comprises propylene glycol monomethyl ether (PGME) (C-1); and:
optionally, the content of PGME (C-1) is 30 to 100 mass % based on the solvent (C);
optionally, the solvent (C) further comprises a solvent (C-2);
optionally, the content of the solvent (C-2) is 0 mass % or more and less than 50 mass %, based on the solvent (C); or
optionally, the solvent (C-2) is selected from the group consisting of alcohol solvents (C-2-1) and low boiling point solvents (C-2-2).

3. The composition according to claim 1, wherein the alkali-soluble resin (A) has a mass average molecular weight of 10,000 to 50,000.

4. The composition according to claim 1, wherein the photoacid generator (B) is represented by the formula (B-1) or formula (B-2): 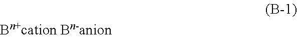
where,
the Bⁿ⁺ cation is a cation represented by the formula (BC1), a cation represented by the formula (BC2), or a cation represented by the formula (BC3), the Bⁿ⁺ cation as a whole is n-valent, and n is 1 to 3, and
the Bⁿ⁻ anion is an anion represented by the formula (BA1), an anion represented by the formula (BA2), an anion represented by the formula (BA3), or an anion represented by the formula (BA4), and the Bⁿ⁻ anion as a whole is n-valent: 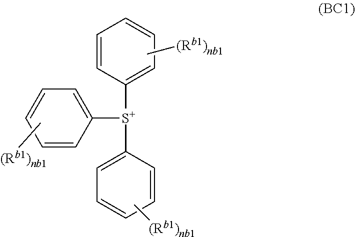
(where,
R^{b1} is each independently C₁₋₆ alkyl, C₁₋₆ alkoxy, C₆₋₁₂ aryl, C₆₋₁₂ arylthio or C₆₋₁₂ aryloxy; and
nb1 is each independently 0, 1, 2 or 3); 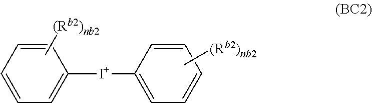
(where,
R^{b2} is each independently C₁₋₆ alkyl, C₁₋₆ alkoxy or C₆₋₁₂ aryl; and
nb2 is each independently 0, 1, 2 or 3); 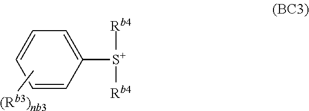
(where,
R^{b3} is each independently C₁₋₆ alkyl, C₁₋₆ alkoxy or C₆₋₁₂ aryl;
R^{b4} is each independently C₁₋₆ alkyl; and
nb3 is each independently 0, 1, 2 or 3); 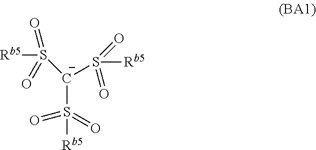
(where,
R^{b5} is each independently C₁₋₆ fluorine-substituted alkyl, C₁₋₆ fluorine-substituted alkoxy, or C₁₋₆ alkyl); 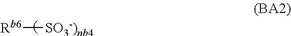
(where,
R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl; and
nb4 is 1 or 2); 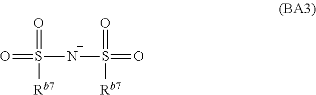
(where,
R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, in which two R^{b7} can be bonded to each other to form a fluorine-substituted heterocyclic structure); 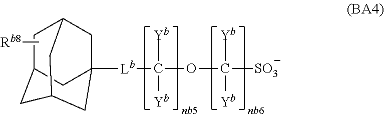
(where,
R^{b8} is hydrogen, C₁₋₆ alkyl, C₁₋₆ alkoxy or hydroxy,
L^{b} is carbonyl, oxy or carbonyloxy;
Y^{b} is each independently hydrogen or fluorine;
nb5 is an integer of 0 to 10; and
nb6 is an integer of 0 to 21); and 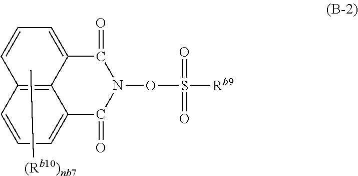
where,
R^{b9} is C₁₋₅ fluorine-substituted alkyl;
R^{b10} is each independently C₃₋₁₀ alkenyl or alkynyl (in which CH₃— in the alkenyl and alkynyl can be substituted with phenyl, and —CH₂— in the alkenyl and alkynyl can be replaced with at least one of —C(═O)—, —O— or phenylene), C₂₋₁₀ thioalkyl, C₅₋₁₀ saturated heterocycle; and
nb7 is 0, 1 or 2.

5. The composition according to claim 1, further comprising a photoreactive quencher (D) represented by the formula (D-1): 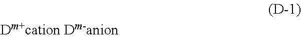
where,
the D^{m+} cation is a cation represented by the formula (DC1) or a cation represented by the formula (DC2), the D^{m+} cation as a whole is m-valent, and m is 1 to 3, and
the D^{m-} anion is an anion represented by the formula (DA1) or an anion represented by the formula (DA2), and the D^{m-} anion as a whole is m-valent: 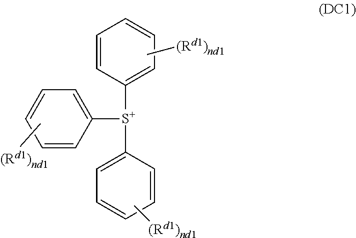
(where,
R^{d1} is each independently C₁₋₆ alkyl, C₁₋₆ alkoxy, C₆₋₁₂ aryl, C₆₋₁₂ arylthio or C₆₋₁₂ aryloxy; and
nd1 is each independently 0, 1, 2 or 3); 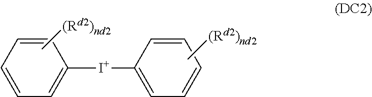
(where,
R^{d2} is each independently C₁₋₆ alkyl, C₁₋₆ alkoxy or C₆₋₁₂ aryl; and
nd2 is each independently 0, 1, 2 or 3); 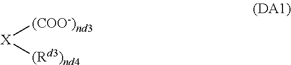
(where,
X is a C₁₋₂₀ hydrocarbon or a single bond,
R^{d3} is each independently hydrogen, hydroxy, C₁₋₆ alkyl or C₆₋₁₀ aryl;
nd3 is 1, 2 or 3; and
nd4 is 0, 1 or 2); 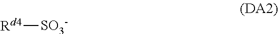
(where,
R^{d4} is C₁₋₁₅ alkyl (in which all or part of the alkyl can form a ring, and —CH₂— in the alkyl can be replaced with —C(═O)—):
optionally, the cationic moiety generated by the photoreactive quencher (D) receiving light is a quencher that reacts with the anionic moiety generated by the photoacid generator (B) receiving light.

6. The composition according to claim 5, further comprising a surfactant (E), and
optionally, further comprising a plasticizer (F); or
optionally, further comprising an additive (G), wherein the additive (G) is at least one selected from the group consisting of a surface smoothing agent, a dye, a contrast enhancer, a base, an acid, a radical generator, a substrate adhesion enhancer and an antifoaming agent.

7. The composition according to claim 6, wherein,
the content of the alkali-soluble resin (A) is more than 0 mass % and 50 mass % or less, based on the composition;
the content of the photoacid generator (B) is more than 0 mass % and 20 mass % or less, based on the alkali-soluble resin (A); and
the content of the solvent (C) is 20 mass % or more and less than 100 mass %, based on the composition; and
optionally, the content of the photoreactive quencher (D) is 0.01 to 5 mass % based on the alkali-soluble resin (A);
optionally, the content of the surfactant (E) is 0.0001 to 1 mass % based on the alkali-soluble resin (A);
optionally, the content of the plasticizer (F) is 0 to 3 mass % based on the composition; or
optionally, the content of the additive (G) is 0.00001 to 10 mass % based on the alkali-soluble resin (A).

8. The composition according to claim 1, which is a thick film chemically amplified positive type KrF resist composition.

9. A method for manufacturing a resist film comprising the following steps:
(1) applying the composition according to claim 1 above a substrate; and
(2) heating the composition to form a resist film; and
optionally, wherein the film thickness of the resist film is 5.0 μm to 50 μm;
optionally, wherein the heating in (2) is performed at 100 to 250° C. and/or for 30 to 300 seconds; or
optionally, wherein the heating in (2) is performed in the air or in a nitrogen gas atmosphere.

10. A method for manufacturing a resist pattern comprising the following steps:
forming a resist film by the method according to claim 9;
(3) exposing the resist film; and
(4) developing the resist film.

11. The method for manufacturing a resist pattern according to claim 10, wherein the ratio of the distance between a perpendicular line from the end point of the top of the resist pattern to the substrate and a perpendicular line from the most recessed point of the side surface of the resist pattern to the substrate to the thickness of the resist film is 0.023 or less.

12. A method for manufacturing a processed substrate comprising the following steps:
forming a resist pattern by the method according to claim 10; and
(5) processing by using the resist pattern as a mask; and
optionally, processing the underlayer or substrate in (5).

13. A method of manufacturing a processed substrate comprising the following steps:
forming a resist pattern by the method according to claim 10;
(5a) etching the resist pattern; and
(5b) etching the substrate:
wherein,
the combination of the steps (5a) and (5b) is repeated at least two times; and
the substrate comprises multiple Si-containing layers, and at least one Si-containing layer is electrically conductive and at least one Si-containing layer is electrically insulating; and
optionally, wherein an electrically conductive Si-containing layer and an electrically insulating Si-containing layer are alternately laminated.

14. A method for manufacturing a processed substrate, comprising the following steps:
manufacturing a resist pattern by the method according to claim 11; and
performing ion implantation using the resist pattern as a mask, or
processing an underlayer of the resist pattern using the resist pattern as a mask to form a underlayer pattern, and performing ion implantation using the underlayer pattern as a mask.

15. A method for manufacturing a device comprising the method according to claim 14; and
optionally, further comprising a step of forming a wiring on the processed substrate; or
optionally, wherein the device is a semiconductor device.

16. A method for manufacturing a device comprising the method according to claim 12; and
optionally, further comprising a step of forming a wiring on the processed substrate; or
optionally, wherein the device is a semiconductor device.

17. A method for manufacturing a device comprising the method according to claim 13; and
optionally, further comprising a step of forming a wiring on the processed substrate; or
optionally, wherein the device is a semiconductor device.
